(19) United States
(12) Patent Application Publication
(10) Pub. No.: US 2011/0127431 A1
(43) Pub. Date: Jun. 2, 2011

(54) PHOTOCONDUCTOR DEVICE HAVING POLYCRYSTALLINE GaAs THIN FILM AND METHOD OF MANUFACTURING THE SAME

(75) Inventor: Mun Cheol PAEK, Daejeon (KR)

(73) Assignee: ELECTRONICS AND TELECOMMUNICATIONS RESEARCH INSTITUTE, Daejeon (KR)

(21) Appl. No.: 12/787,841

(22) Filed: May 26, 2010

(30) Foreign Application Priority Data
Dec. 2, 2009 (KR) 10-2009-0118339

(51) Int. Cl. H01L 31/0304; H01L 31/18; H01L 31/09; H01L 31/0232; H01L 33/58; H01L 33/02

(52) U.S. Cl. 250/338.4; 438/25; 250/504 R; 257/E31.019; 257/E31.127; 257/E31.093; 257/E33.068; 257/E33.024

(57) ABSTRACT

A photoconductor device and a method of manufacturing the same are provided. The photoconductor device includes a photoconductor substrate, a photoconductor thin film deposited on the photoconductor substrate, and a photoconductive antenna electrode formed on the photoconductor thin film. The photoconductor thin film includes polycrystalline GaAs.

### CROSS-REFERENCE TO RELATED APPLICATION

This application claims priority to and the benefit of Korean Patent Application No. 10-2009-0118339, filed Dec. 2, 2009, the disclosure of which is incorporated herein by reference in its entirety.

### BACKGROUND

1. Field of the Invention

The present invention relates to a photoconductor device which generates or detects a terahertz (THz) wave, and more particularly, to a material for a photoconductor device.

2. Discussion of Related Art

A terahertz (THz) wave is an electromagnetic wave which corresponds to a frequency domain between 0.1 THz to 10 THz and is an intermediate wave between a radio wave and a light wave. The THz wave has a shorter wavelength than a radio wave with the shortest wavelength, a millimeter wave, and a longer wavelength than a light wave with the longest wavelength, a far infrared ray. One (1) THz is a value which corresponds to a wavelength of 30 μm, a wave number of 33.3 cm⁻¹, a time of one pico (10⁻¹²) second, a energy of 4.1 meV, and an absolute temperature of 46 K. Research and development on the THz wave has not been as actively conducted as that on radio wave technology such as microwaves and millimeter waves and light wave technology such as far infrared rays and mid infrared rays since there was no appropriate technique for generating and detecting the THz wave. With brilliant development of science and technology, there have been many achievements in this field over the past decades. Interests on the THz wave have increased, and the prospects of the THz wave for expansion of application fields and economical efficiency as a future frequency resource are bright.

The THz wave has its own unique characteristics and thus various applications such as medical diagnosis, biological sample analysis, security observation, farm product and foodstuff inspection, environmental inspection, and wireless communications are being anticipated. That is, the THz wave has both transmittivity of the radio wave and directionality of the light wave, and spectroscopic analysis which is carried out in infrared rays, visible rays, or x-rays can be performed. Particularly, since time-domain spectroscopy detects and analyzes the THz wave having data in time units, it can simultaneously acquire amplitude information and phase information, so that various data for samples can be obtained, compared to other spectroscopies.

A frequency domain of the THz wave corresponds to an intermolecular vibration frequency of organic and inorganic materials, and it is possible to obtain information such as a fingerprint inherent to a sample for movement and twist of molecules and a molecular binding state. Due to the above-described characteristics, a technique using the THz wave can be usefully used in identifying unidentified materials or detecting a specific component such as a drug. This technique can be used in analyzing a unique characteristic of information of a biological material containing water such as a foodstuff or biological sample.

Further, the THz wave has high transmittance for organic materials excluding metal and thus can obtain a transmission image such as an x-ray fluoroscopic image. This is a result of adding transmittivity of the radio wave to directionality of the light wave. Unlike x rays, the THz wave is very low in photon energy and does not cause a photoionization reaction in samples, and thus the THz wave does not damage biological samples. This is the reason why the THz wave is called T rays as a relative concept of x rays as a function of obtaining a fluoroscopic image which does not harm a human body. Using the THz wave which has both a spectroscopic function and a transmitting function, a dangerous material, a drug, and a weapon contained in mail can be detected without opening the mail.

Further, the THz wave is evaluated as a very important alternative which makes ultra-high capacity broadband wireless communication possible in the wireless communication field in which frequency will be exhausted in the future due to limitations of current frequency resources. When high-quality moving pictures of a HD TV level are generally used in portable information devices in the future, a wireless transmission function is expected as an indispensable technique. However, since current techniques use data compression, problems such as time delay or deterioration of image quality occur. In order to wirelessly transmit data without compression, a data transmission rate has to increases in units of 1 to 10 Gbps, but a band of current of several GHz as a carrier frequency for realizing the transmission rate is expected to face its limit soon. Therefore, high frequency resources of higher than 100 GHz, i.e., 0.1 THz, are required.

Many methods of generating and detecting the THz wave have been developed, and an appropriate technique is applied according to a usage, a bandwidth, and a frequency domain. A photoconductive switching technique is commonly used for spectrum and image. Embodiments of the present invention are suggested to solve a problem of the photoconductive switching technique. The photoconductive switching technique involves irradiating a femtosecond laser, which is an ultra-short pulse laser, to a photoconductor and generating electron-hole pairs. The photoconductor uses a single crystalline thin film which is grown on a substrate at a low temperature and forms an electrode of a dipole or parallel line form thereon using metal. FIG. 1 illustrates a photoconductor device. A distance between electrodes is about 5 to 10 μm, and a bias voltage of about 10 to 50 volts is applied to both ends. In this state, an ultra-short laser pulse is irradiated to the photoconductor film between the electrodes. As a result, electron-hole pairs are formed in the photoconductor by the strong pulse, and a photocurrent flows by the bias voltage applied between the electrodes. The photoelectric current is shown in response to the irradiated laser pulse and thus generated during a very short time of less than a picosecond with respect to a laser pulse of femtoseconds level. As in the following equation (1), an electromagnetic wave is generated due to a change in photoelectric current, and an electric field of the electromagnetic wave is proportional to a change rate of the photocurrent.

$${E}_{THz} ( t ) ∝ \frac{\partial {j}_{em} ( t )}{\partial t} \qquad Equation ( 1 )$$

where E_{THz}(t) denotes an electromagnetic field of a generated THz wave, and jₑₘ(t) denotes a photoelectric current density. In order to generate an electric field of a THz area, the photocurrent should be generated and disappear in short time. To this end, the photoconductor needs characteristics of high dark resistivity, high mobility, and short carrier lifetime.

There are many materials for the photoconductor which satisfy the characteristics. A single crystalline material which is grown at a low temperature is commonly used because the material characteristics can be adjusted by artificially adjusting a crystal defect. Particularly, a method of adjusting density and distribution of the crystal defect by high-density ion implantation of an element with a large atomic number is commonly used. This brings an effect of increasing recombination opportunities of generated electron-hole pairs and thereby shortening a life time of a charge carrier, due to the crystal defect present inside the thin film. Further, since a thin film is deposited in a single crystalline form using ultra-high vacuum equipment such as a molecular beam epitaxy system, mobility is improved and dark resistivity is increased.

A photoconductive switching device which is almost the same as in the case of generating the THz wave is used to detect the THz wave. For the sake of detection efficiency, a configuration of electrodes is slightly changed, and a bias is not applied between the electrodes. A femtosecond laser pulse is irradiated with a predetermined time delay compared to the case of generation. Electron-hole pairs are generated even in the photoconductor of the detector by the laser pulse, but since a bias voltage is not applied, a photocurrent is not detected therein. However, when a signal THz wave is irradiated to the photoconductor, a voltage is generated between the electrodes due to the electric field generated by the THz wave, and this current follows a waveform of the THz wave. Therefore, the THz waveform can be detected by sequentially irradiating an ultra-short pulse with a time delay. This is referred to as a photoconductive switching sampling technique.

There are many factors for determining the performance of the generator and detector, but characteristics of the photoconductor and device serve as one of the most important factors. Generally, when a signal to noise ratio of the detected THz wave is equal to or more than 10⁴, it is determined as a usable level, and when equal to or more than 10⁶, it is determined as an excellent level. As a frequency range widens toward a short wavelength domain according to its usage, a spectrum range also widens. To this end, characteristics of a photoconductive material and device may be precisely controlled.

### SUMMARY OF THE INVENTION

The present invention is directed to a photoconductor device having a polycrystalline GaAs thin film and a method of manufacturing the same in which the above-mentioned problems of a single crystalline material used in the photoconductor are solved. In order to obtain an existing single crystalline material, high-price equipment called a molecular beam epitaxy system has to be used, and the crystal defect has to be controlled through a very precise process. Further, long-term use changes a defect distribution and a characteristic, leading to low reliability. This reduces productivity and increases the price in the case of commercialization. Further, in the case of actual use, in order to obtain spectrum information, it is necessary to obtain a reference spectrum of the terahertz (THz) wave itself. However, since the status of the photoconductor and device varies from time to time depending on ambient temperature, an electrical characteristic, and the frequency of practical use, it is necessary to continuously measure and detect for actual stable application. Therefore, the method most commonly used now employs the single crystalline material, but in order to prepare for future mass demand, reliability, reproducibility, and economical efficiency of a material have to be secured.

An aspect of the present invention provides a photoconductor device, including: a photoconductor substrate; a photoconductor thin film deposited on the photoconductor substrate; and a photoconductive antenna electrode formed on the photoconductor thin film. Here, the photoconductor thin film includes polycrystalline GaAs.

The photoconductor device may further include a voltage source which applies a bias voltage to the photoconductive antenna electrode to generate a THz wave.

The photoconductor device may further include a current meter which measures an electric current flowing through the photoconductive antenna electrode to detect a THz wave.

The photoconductor device may further include a hemispherical lens disposed on a surface of the photoconductor substrate which is opposite to a surface on which the photoconductor thin film is deposited.

The photoconductor substrate may be made of sapphire or high-resistive silicon.

The photoconductor thin film may be formed by a sputtering technique or a metalorganic chemical vapor deposition (MOCVD) technique.

The photoconductor thin film may be formed by growing a thin film without doping an impurity.

Another aspect of the present invention provides a method of manufacturing a photoconductor device, including: preparing a photoconductor substrate; depositing a photoconductor thin film including polycrystalline GaAs on the photoconductor substrate; and forming a photoconductive antenna electrode on the photoconductor thin film.

The method may further include: patterning the photoconductor thin film; and cutting the photoconductor substrate on which the photoconductor thin film is deposited through a sawing process.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1A and 1B illustrate the configuration of photoconductor devices for generating and detecting a terahertz (THz) wave according to an exemplary embodiment of the present invention;

FIGS. 2A and 2B illustrate a time-domain waveform and a frequency-domain spectrum of a THz wave generated and detected by the THz wave generating device and the THz wave detecting device of FIGS. 1A and 1B;

FIGS. 3A and 3B illustrate transmission electron microscope (TEM) images of a single crystalline LT-GaAs which is grown at low temperature;

FIGS. 4A and 4B illustrate a TEM image and an electron beam diffraction pattern of a polycrystalline GaAs thin film formed according to an exemplary embodiment of the present invention;

FIGS. 5A to 5F are cross-sectional views of a photoconductor device for explaining a method of manufacturing a photoconductor device which generates or detects the THz wave according to an exemplary embodiment of the present invention; and

FIGS. 6A and 6B are graphs illustrating detection characteristics of a THz wave for low temperature (LT)-GaAs thin films in a time domain and a frequency domain as a result of an experiment for testing a THz wave detection characteristic of a polycrystalline GaAs thin film formed according to an exemplary embodiment of the present invention.

### DETAILED DESCRIPTION OF PREFERRED EMBODIMENTS

Hereinafter, exemplary embodiments of the present invention will be described in detail. However, the present invention is not limited to the embodiments disclosed below, but can be implemented in various forms. The following embodiments are described in order for this disclosure to be complete and enabling to those of ordinary skill in the art.

When an element is referred to as being “on” or “below” another element, it can be directly on or directly below the other element or layer, or intervening elements may be present. In the drawings, the size and relative sizes of layers and regions may be exaggerated for clarity.

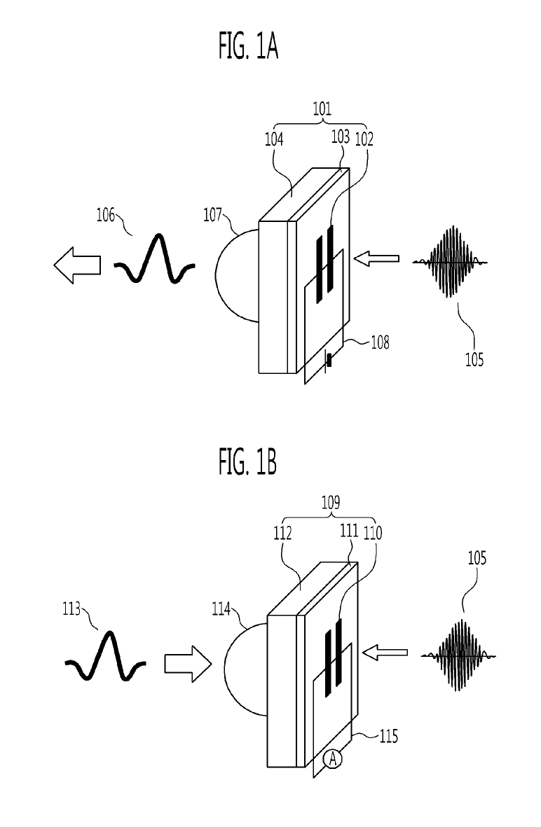

A photoconductive antenna device using a polycrystalline GaAs thin film according to an exemplary embodiment of the present invention will be described below with reference to FIGS. 1A and 1B.

FIGS. 1A and 1B illustrate the configuration of a photoconductive antenna using a polycrystalline GaAs thin film as a device for generating and detecting the terahertz (THz) wave and a principle of generating and detecting the THz wave according to an exemplary embodiment of the present invention.

Referring to FIG. 1, a THz wave generating device 101 according to an exemplary embodiment of the present invention includes photoconductive antenna electrodes 102, a photoconductor thin film 103, and a photoconductor substrate 104. The photoconductor thin film 103 is deposited on the photoconductor substrate 104. Single crystalline GaAs which is grown at low temperature may be used as the photoconductor thin film 103, but polycrystalline GaAs is preferably used according to an exemplary embodiment of the present invention. The photoconductive antenna electrodes 102 are formed on the photoconductor thin film 103. The photoconductor substrate 104 may be made of semi-insulating GaAs. When the photoconductor thin film 103 is formed of a polycrystalline GaAs thin film, sapphire or high-resistive silicon may be used as a material of the photoconductor substrate 104. The photoconductive antenna electrodes 102 may have a form of a parallel metal transmission line or a form of a parallel metal transmission line with a central protruding portion.

In order to generate the THz wave, a femtosecond laser pulse 105 with a pulse time of 10 to 100 fs generated by an ultra-short pulse laser is needed. In order to concentrate the generated THz wave 106 in a predetermined direction, a hemispherical lens 107 which is transparent to the THz wave and has a large refractive index is used. The hemispherical lens 107 may be made of high-resistive silicon. The hemispherical lens 107 is disposed on a surface of the photoconductor substrate 104 which is opposite to a surface on which the photoconductor thin film 103 is deposited.

A principle of generating the THz wave will be described below with reference to FIG. 1A. An ultra-short pulse femtosecond laser 105 is irradiated between the antenna electrodes 102 to which a DC bias 108 of 10 to 50 V is applied, so that electron-hole pairs are generated in the photoconductor thin film 103. Charges move toward the both electrodes by the bias, so that the photocurrent is generated. The photocurrent flows during a very short time due to an ultra-short pulse. At this time, an electromagnetic field is formed due to a change in the photocurrent, and when a moving time of the charge carriers is as short as a picosecond, the electromagnetic field becomes the THz wave 106. The THz wave is generated and emitted in the whole space, but since a dielectric constant of the photoconductor thin film 103 and the substrate 104 is much greater than a free space, the THz wave 106 is emitted toward the substrate 104. The silicon lens 107 is used to concentrate the THz wave in one direction.

FIG. 1B illustrates the configuration of a THz wave detecting device 109 according to an exemplary embodiment of the present invention. The THz wave detecting device 109 has a structure and a material which are almost the same as the THz wave generating device 101, and thus descriptions thereof are omitted. Detecting antenna electrodes 110 may be changed in form in order to improve a detection characteristic, and a detecting photoconductor thin film 111 and a substrate 112 may be made of materials different from those of the THz wave generating device 101. An electro-optic crystal such as ZnTe may be used. Similarly to the THz wave generating device 101, the femtosecond laser pulse 105 is necessary and irradiated between the electrodes 110 as in FIG. 1. The femtosecond pulse laser is irradiated with a time delay of a predetermined interval by a time delay device for the sake of sampling detection.

Referring to FIG. 1B, unlike the THz wave generating device 101, a DC bias is not applied to the THz wave detecting device 109, and a form of the electrodes may be slightly changed. A detection principle is as follows. A THz wave 113 which has been generated by the THz wave generating device 101 and then passed through the free space or a test sample is irradiated to the THz wave detecting device 109 through a hemispherical lens 114. In the photoconductor thin film 111, electron-hole pairs are generated by the femtosecond laser pulse 105 and move toward the electrodes by the electric field of the irradiated THz wave 113, so that the photocurrent flows. The photocurrent is measured by a current meter 115. Since a change in the photocurrent represents a change in the electromagnetic field by the THz wave, the waveform of the THz wave can be measured by sampling and measuring the change in the photocurrent in units of less than a picosecond through the delay time.

A photoconductor material for generating and detecting the THz wave needs to satisfy requirements in which a life span of a charge carrier is short, mobility is large, and a breakdown voltage is high.

In the single crystalline GaAs thin film which is grown at low temperature, since a high quality thin film is grown at low temperature in the atmosphere having a lot of arsenic (As) by using molecular beam epitaxy (MBE), arsenic ions are excessively present in the thin film, and arsenic precipitates are generated by subsequent heat treatment to form the crystal defect. Therefore, the recombination speed of the charge carriers such as electrons or holes increases, so that the above-mentioned material requirements are satisfied. However, according to an exemplary embodiment of the present invention, a polycrystalline GaAs thin film is used instead of the single crystalline thin film. An experiment has shown that a THz wave generating characteristic in the polycrystalline GaAs thin film is the same as or more excellent than the single thin film. The polycrystalline thin film has advantages in that it can be deposited on silicon, sapphire, and glass substrates without depending on the characteristics of the substrate and it does not need to use high-priced equipment such as the MBE system. In selecting a substrate material, crystallinity related to the growth of the thin film and transmittivity of the generated THz wave should be considered. In the case of using the polycrystalline GaAs thin film, a range of selecting the substrate material is broadened. Therefore, there is a large influence from a technical point of view as well as an economical point of view.

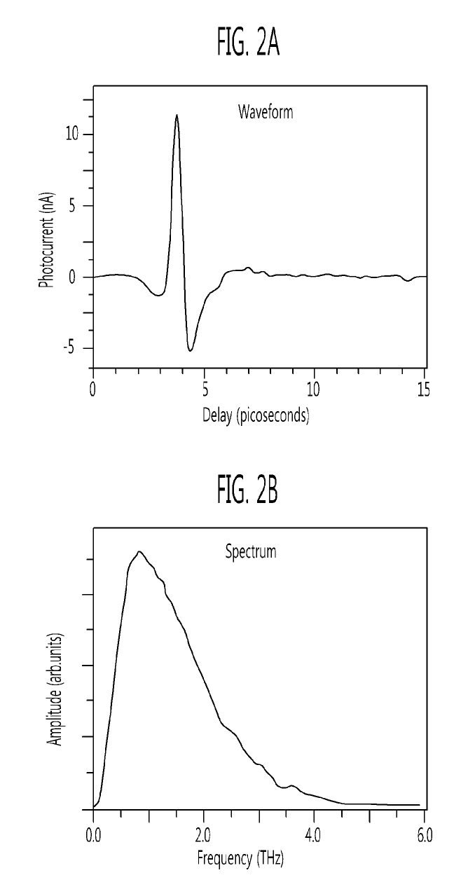

FIGS. 2A and 2B illustrate waveforms of the THz wave generated and detected by the THz wave generating device 101 and the THz wave detecting device 109. FIG. 2A illustrates the waveforms measured in the time domain, and FIG. 2B illustrates the waveforms measured in the frequency domain transformed by the Fourier transform. As can be seen in FIG. 2B, the frequency domain of the THz wave generated and detected by the above-mentioned method commonly reaches a range of 0 to 4 THz.

As described above, in generating and detecting the THz wave using the photoconductive switching method, a characteristic of the photoconductor material is one of the most important factors, and particularly, a characteristic of the THz wave depends on a change in the photoelectric current. In the low temperature (LT)-GaAs of the single crystalline state, a method of artificially generating the crystal defect when growing the high quality single crystalline thin film is used in order to reduce the lifetime of the electron carrier. In this case, however, there are problems in that it is difficult to grow the thin film having high reliability and reproducibility depending on a processing method and a reference value easily changes during use depending on a change in the ambient environmental. However, the problems are solved by using the polycrystalline GaAs thin film.

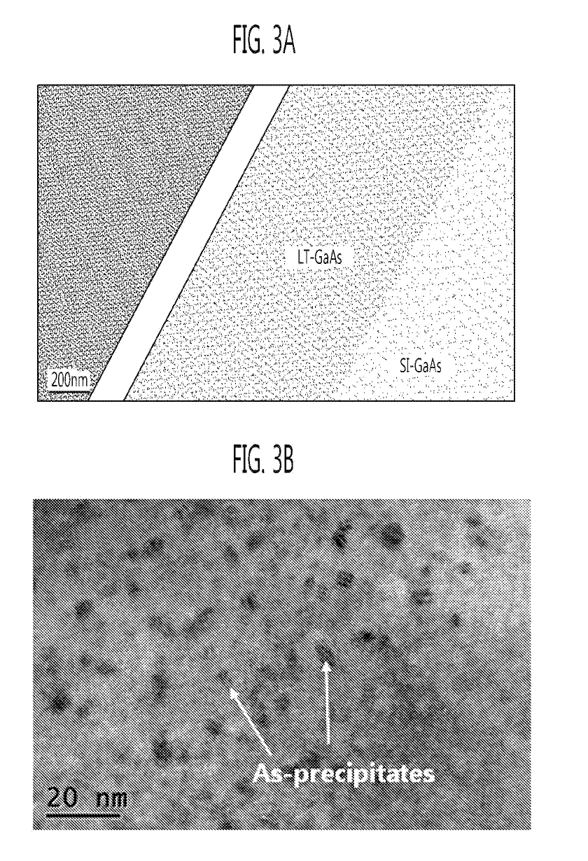

FIGS. 3A and 3B illustrate high-resolution transmission electron microscope (TEM) images of the single crystalline LT-GaAs, which is grown on a semi-insulating GaAs substrate, as the photoconductor material. As illustrated in FIG. 3A, it can be understood that the crystal defects (such as arsenic (As) precipitates) having the diameter of tens of nanometers (nm) are uniformly distributed throughout the thin film. In the case of observing with high resolution, as illustrated in FIG. 3B, it can be understood that As precipitates which are as small as an atom are distributed. The crystal defects increase the recombination frequency of the electron carriers as described above and thus greatly reduce their lifetime.

According to an exemplary embodiment of the present invention, suggested is a method of forming the polycrystalline GaAs thin film by further reducing growth temperature when growing the LT-GaAs thin film or using a substrate having different crystallinity.

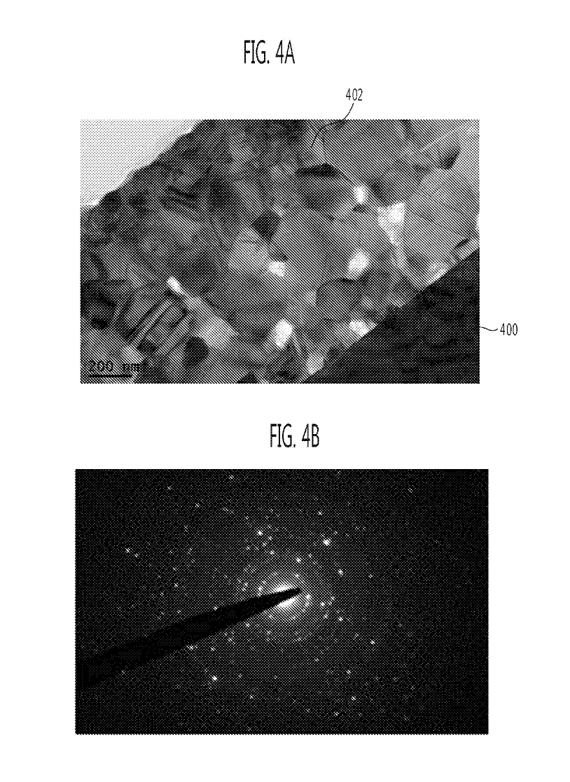

FIG. 4A illustrates a TEM image of a polycrystalline thin film 402 which is grown on a semi-insulating GaAs substrate 400 at a low temperature of 150□ using an MBE technique. Referring to FIG. 4A, grains and the grain boundaries are present in the polycrystalline GaAs thin film 402. Referring to FIG. 4B, it can be understood through an electron beam diffraction pattern of the polycrystalline GaAs thin film 402 that a polycrystalline state is present. Referring to FIG. 4C, however, it can be understood through an electron beam diffraction pattern of the semi-insulating GaAs substrate 400 that a single crystalline state is present because a diffraction pattern has a regular arrangement.

In the grain boundary inside the polycrystalline thin film, a bond between GaAs atoms is unstable, a crystalline structure is not perfect, and it is a portion having high energy. Therefore, generated electron-hole pairs are easily recombined in the grain boundary. This plays the same role as the crystal defects artificially formed in the single crystalline LT GaAs thin film, and since there are many grain boundaries in the polycrystalline structure, this greatly reduces the lifetime of the carriers. Further, inside the grain, the same crystalline structure as the single crystal is present, and mobility of the electron carriers is high. Therefore, the photocurrent flows rapidly during a short time. A general poly crystal causes a dark current since impurities are precipitated in the grain boundaries and thus frequently causes an abnormal operation of a device. This is one of the reasons that the poly crystal is not widely used in thin films requiring high quality. However, according to an exemplary embodiment of the present invention, since the thin film is grown without doping impurities, the dark current is not increased, and the THz wave has a signal to noise ratio of more than 10⁴. Therefore, the requirements of the photoconductor for generating the THz wave are satisfied, and there are effects in reliability, reproducibility and from an economical point of view.

Next, a method of manufacturing a photoconductor device according to an exemplary embodiment of the present invention will be described.

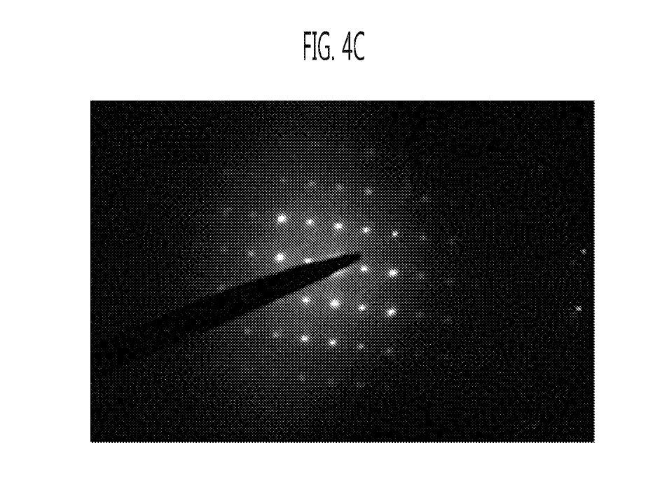

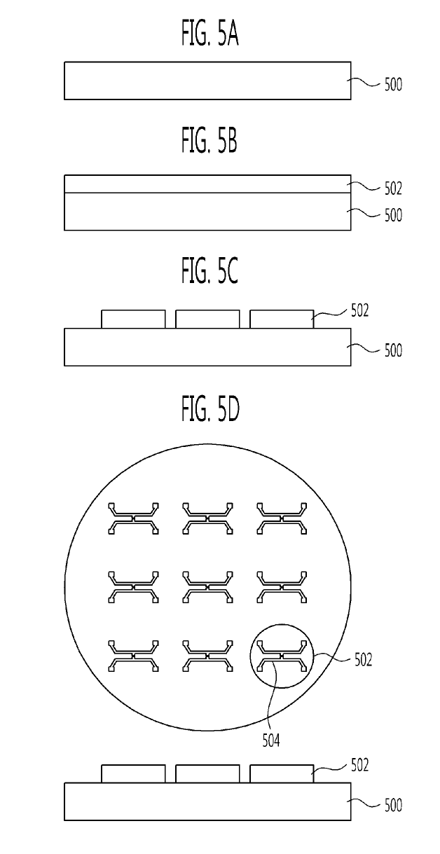

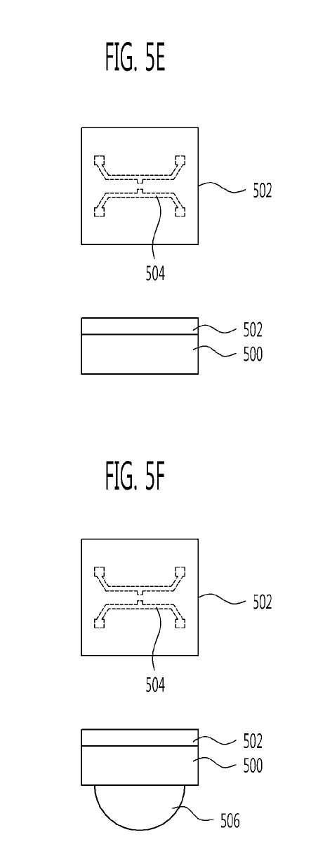

FIGS. 5A to 5F are cross-sectional views of a photoconductor device for explaining a method of manufacturing a photoconductor device which generates or detects a THz wave according to an exemplary embodiment of the present invention.

Referring to FIG. 5A, a photoconductor substrate 500 is prepared. The photoconductor substrate 500 may be made of semi-insulating GaAs, sapphire or high-resistive silicon.

Referring to FIG. 5B, a photoconductor thin film 502 is formed on the photoconductor substrate 500. The photoconductor thin film 500 may include a polycrystalline GaAs thin film. When forming the polycrystalline GaAs thin film, a sputtering technique or a metalorganic chemical vapor deposition (MOCVD) technique may be used. This makes mass production possible, and thus a thin film which is low in processing cost and high in reliability can be formed.

Referring to FIG. 5C, the photoconductor thin film 502 is patterned.

Referring to FIG. 5D, photoconductive antenna electrodes 504 are formed on the photoconductor thin film 502. The photoconductive antenna 504 may have the shape of a parallel metal transmission line having a central protruding portion. The central protruding portion of the photoconductive antenna 504 serves as a small dipole antenna.

Referring to FIG. 5E, the photoconductor thin film 502 and the photoconductor substrate 500 are cut into a predetermined size by a sawing process.

Referring to FIG. 5F, a hemispherical lens 506 is formed on a surface of the photoconductor substrate 500 which is opposite to a surface on which the photoconductor thin film 502 is deposited. The hemispherical lens 506 may be formed of silicon.

Thereafter, as illustrated in FIG. 1A, a voltage source 108 which applies a bias voltage to the photoconductive antenna electrodes 504 may be formed, so that the device can be used for generating the THz wave. Further, as illustrated in FIG. 1B, a current meter 115 which measures an electric current flowing through the photoconductive antenna electrodes 504 may be formed, so that the device can be used for detecting the THz wave.

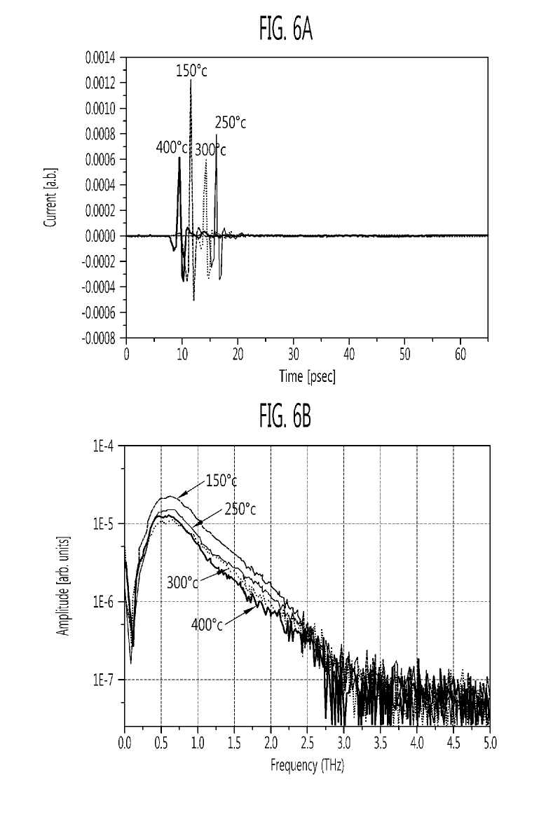

FIGS. 6A and 6B are graphs illustrating detection effects of a THz wave for GaAs thin films which are grown at different temperatures as an experiment related to the present invention. At a temperature higher than 150□, a GaAs thin film of a single crystalline state having many crystal defects was formed, and a polycrystalline thin film was grown at a temperature of 150□. The polycrystalline thin film showed excellent THz wave detection effect. Referring to FIG. 6A, it can be understood that a signal of the THz wave measured in the time domain has the highest value in the polycrystalline GaAs thin film. Referring to FIG. 6B, it can be understood that a signal of the THz wave measured in the frequency domain also has the most excellent value in the polycrystalline GaAs thin film.

A GaAs thin film which was grown on a sapphire substrate showed almost the same result, and all showed a value higher than the single crystalline GaAs thin film. This represents that low-priced equipment can be used instead of the high-priced MBE system, and the low-priced sapphire substrate can be used instead of the high-priced GaAs substrate. Since sapphire is transparent to the THz wave, there is no need to worry about a phenomenon that the efficiency is reduced at the time of optical detection and generation.

As described above, according to an exemplary embodiment of the present invention, a polycrystalline GaAs thin film is used as a photoconductor material instead of a single crystalline thin film, and thus the price for forming a poly crystal is lowered and reliability is increased. Since the polycrystalline GaAs thin film is grown regardless of crystallinity and a crystalline direction of a substrate, there is no limitation in which only a substrate of a semi-insulating material has to be used like an existing single crystalline material, and it can be grown on a silicon substrate or a sapphire substrate. Further, as a growing technique, a sputtering technique or a MOCVD technique can be used instead of using high-priced equipment such as an MBE system. This makes mass production possible, and thus a thin film in which a process price is low and reliability is high can be manufactured.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A photoconductor device, comprising:
a photoconductor substrate;
a photoconductor thin film deposited on the photoconductor substrate; and
a photoconductive antenna electrode formed on the photoconductor thin film,
wherein the photoconductor thin film includes polycrystalline GaAs.

2. The photoconductor device of claim 1, further comprising a voltage source which applies a bias voltage to the photoconductive antenna electrode to generate a terahertz wave.

3. The photoconductor device of claim 1, further comprising a current meter which measures an electric current flowing through the photoconductive antenna electrode to detect a terahertz wave.

4. The photoconductor device of claim 1, further comprising a hemispherical lens disposed on a surface of the photoconductor substrate which is opposite to a surface on which the photoconductor thin film is deposited.

5. The photoconductor device of claim 1, wherein the photoconductor substrate is made of sapphire or high-resistive silicon.

6. The photoconductor device of claim 1, wherein the photoconductor thin film is formed by a sputtering technique or a metalorganic chemical vapor deposition (MOCVD) technique.

7. The photoconductor device of claim 1, wherein the photoconductor thin film is formed by growing a thin film without doping an impurity.

8. A method of manufacturing a photoconductor device, comprising:
preparing a photoconductor substrate;
depositing a photoconductor thin film including polycrystalline GaAs on the photoconductor substrate; and
forming a photoconductive antenna electrode on the photoconductor thin film.

9. The method of claim 8, further comprising:
patterning the photoconductor thin film; and
cutting the photoconductor substrate on which the photoconductor thin film is deposited through a sawing process.

10. The method of claim 8, further comprising forming a voltage source which applies a bias voltage to the photoconductive antenna electrode to generate a terahertz wave.

11. The method of claim 8, further comprising forming a current meter which measures an electric current flowing through the photoconductive antenna electrode to detect a terahertz wave.

12. The method of claim 8, further comprising forming a hemispherical lens on a surface of the photoconductor substrate which is opposite to a surface on which the photoconductor thin film is deposited.

13. The method of claim 8, wherein the photoconductor substrate is made of sapphire or high-resistive silicon.

14. The method of claim 8, wherein the photoconductor thin film is formed by a sputtering technique or a metalorganic chemical vapor deposition (MOCVD) technique.

15. The method of claim 8, wherein the photoconductor thin film is formed by growing a thin film without doping an impurity.
